(19) United States
(12) Patent Application Publication
(10) Pub. No.: US 2024/0188448 A1
(43) Pub. Date: Jun. 6, 2024

(54) MULTIPLE LAYERS OF VOID-FREE INTERLAYER DIELECTRIC BETWEEN ADJACENT MAGNETORESISTIVE RANDOM-ACCESS MEMORY DEVICES

(71) Applicant: International Business Machines Corporation, Armonk, NY (US)

(72) Inventors: Oscar van der Straten, Guilderland Center, NY (US); Chih-Chao Yang, Glenmont, NY (US)

(21) Appl. No.: 18/060,985

(22) Filed: Dec. 2, 2022

(51) Int. Cl. H01L 43/02; H01L 27/22; H01L 43/12

(52) U.S. Cl. CPC H01L 43/02; H01L 27/222; H01L 43/12

(57) ABSTRACT

A semiconductor structure with a magnetic tunnel junction (MTJ) pillar for a magnetoresistive random-access memory (MRAM) device, where each material layer of the MTJ pillar resides on a lower material layer of the MTJ pillar with a different width. Embodiments of the present invention provide a top electrode with a tapered shape. Embodiments of the present invention also provide a dielectric encapsulation layer around the reference layer and around the free layer. The dielectric encapsulation material surrounding a sidewall of the reference layer is composed of a different dielectric encapsulation material than the dielectric encapsulation around the sidewall of the free layer.

### BACKGROUND

The present invention relates generally to the field of semiconductor device manufacture and more particularly to the formation of magnetoresistive random-access memory (MRAM) device structures.

Increasing computing function requiring both more device circuits and faster processing speeds continues for computer systems and applications. In particular, the use of deep neural networks is becoming pervasive in many end-use computer applications. Deep neural networks are typically used in artificial intelligence (AI) applications. The training of deep neural networks puts significant demand on the memory system in computer systems executing AI with deep neural networks. In response to the demands for increasing memory, memory devices, such as magnetic random-access memory devices are formed in large numbers with a small space between each memory device.

Magnetoresistive random-access memory (MRAM) is a type of non-volatile random-access memory that stores data in magnetic domains. Magnetoresistive Random Access Memory (MRAM), based on the integration of silicon-based complementary silicon-oxide semiconductor (CMOS) with magnetic tunnel junction (MTJ) technology, is a developing non-volatile memory technology using vertical structures or pillars containing magnetic tunnel junctions. MRAM technology provides many advantages in terms of writing/read speed, power consumption, and lifetime over other commercialized memory types including SRAM, DRAM, Flash, etc. Conventional MRAM devices include a magnetic tunnel junction (MTJ) structure having magnetic layers separated by an intermediary non-magnetic tunnel barrier layer. Digital information can be stored in the memory element and can be represented by directions of magnetization vectors. In response to the current applied to the MTJ, the magnetic memory element exhibits different resistance values and allows an MRAM device to provide information stored in the magnetic memory element. Typically, MRAM devices may be fabricated with a field-effect transistor (FET) which can access the MRAM device.

### SUMMARY

Embodiments of the present invention disclose a semiconductor structure with a magnetic tunnel junction (MTJ) pillar for a magnetoresistive random-access memory (MRAM) device, where each material layer of the MTJ pillar resides on a lower material layer of the MTJ pillar with a different width. Embodiments of the present invention provide a top electrode with a tapered shape. Embodiments of the present invention also provide a dielectric encapsulation layer around the reference layer and around the free layer where the dielectric encapsulation material for the reference layer is composed of a different dielectric encapsulation material than the dielectric encapsulation around the free layer.

Embodiments of the present invention disclose a method of forming two adjacent bottom electrodes in a first layer of ILD material above a portion of a first metal layer of a middle-of-line metal layer or a back end of line semiconductor layer. The method includes depositing a reference layer on two adjacent bottom electrodes and the first layer of ILD material. The method includes patterning a hardmask on the reference layer. The method includes removing exposed portions of the reference layer and removing the hardmask. Furthermore, the method includes forming a sidewall encapsulation around the remaining portions of the reference layer and depositing a second layer of ILD material over the semiconductor structure. The method includes depositing a tunnel barrier layer over the remaining portions of the reference layer, the sidewall encapsulant, and the second layer of ILD material and forming two adjacent portions of the tunnel barrier layer using a patterned hardmask. The method includes depositing and planarizing a third layer of ILD material on the second layer of ILD material and the two adjacent portions of the tunnel barrier layer. Additionally, the method includes depositing a free layer on the two adjacent portions of the tunnel barrier layer and the third layer of ILD material and patterning the free layer to form two adjacent portions of the free layer on the two adjacent portions of the tunnel barrier layer. The method includes forming a sidewall encapsulant around the two adjacent portions of the free layer and depositing a fourth layer of ILD material on the semiconductor structure. The method includes forming two adjacent top electrodes on the two adjacent portions of the free layer using an angled ion beam etch process and depositing a fifth layer of ILD material on the fourth layer of ILD material and the two adjacent top electrodes.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a cross-sectional view of a semiconductor structure after forming a metal cap on a metal pad in a dielectric cap layer in accordance with an embodiment of the present invention.

FIG. 2A depicts a cross-sectional view of the semiconductor structure after depositing and patterning an interlayer dielectric (ILD) material over the metal cap and the dielectric cap layer in accordance with an embodiment of the present invention.

FIG. 2B depicts a cross-sectional view of the semiconductor structure after forming a bottom electrode in accordance with an embodiment of the present invention.

FIG. 3 depicts a cross-sectional view of the semiconductor structure after depositing a reference layer of the magnetic tunnel junction (MTJ) over the bottom electrode and ILD in accordance with an embodiment of the present invention.

FIG. 4 depicts a cross-sectional view of the semiconductor structure after depositing and patterning a layer of hardmask on the reference layer in accordance with an embodiment of the present invention.

FIG. 5 depicts a cross-sectional view of the semiconductor structure after etching exposed portions of the reference layer in accordance with an embodiment of the present invention.

FIG. 6 depicts a cross-sectional view of the semiconductor structure after removing the portions of the hardmask in accordance with an embodiment of the present invention.

FIG. 7 depicts a cross-sectional view of the semiconductor structure after depositing a layer of encapsulation material and etching back the encapsulation material in accordance with an embodiment of the present invention.

FIG. 8 depicts a cross-sectional view of the semiconductor structure after depositing a layer of ILD material around the encapsulation material and on the reference layer and performing a chemical-mechanical polish (CMP) in accordance with an embodiment of the present invention.

FIG. 9 depicts a cross-sectional view of the semiconductor structure after depositing a tunnel barrier layer and patterning a hardmask deposited on the tunnel barrier layer in accordance with an embodiment of the present invention.

FIG. 10 depicts a cross-sectional view of the semiconductor structure after removing exposed portions of the tunnel barrier layer and removing the hardmask in accordance with an embodiment of the present invention.

FIG. 11 depicts a cross-sectional view of the semiconductor structure after depositing an ILD material layer, performing a chemical-mechanical polish, depositing and patterning a free layer using the patterned hardmask in accordance with an embodiment of the present invention.

FIG. 12 depicts a top view of the semiconductor structure after depositing a layer of encapsulation material in accordance with an embodiment of the present invention.

FIG. 13 depicts a cross-sectional view of the semiconductor structure after etching horizontal portions of the encapsulation material, depositing a layer of ILD material, and performing a chemical-mechanical polish in accordance with an embodiment of the present invention.

FIG. 14 depicts a cross-sectional view of the semiconductor structure after depositing a layer of electrode material, a layer of hardmask material over the electrode material, and patterning the hardmask material in accordance with another embodiment of the present invention.

FIG. 15 depicts a cross-sectional view of the semiconductor structure after removing exposed portions of the electrode material in accordance with an embodiment of the present invention.

FIG. 16 depicts a cross-sectional view of the semiconductor structure after removing the portions of the hardmask on the top electrode in accordance with an embodiment of the present invention.

FIG. 17 depicts a cross-sectional view of the semiconductor structure after depositing a layer of ILD on the top electrodes and the planarized ILD around the encapsulant of the sidewall of the free layer in accordance with an embodiment of the present invention.

FIG. 18 depicts a cross-sectional view of the semiconductor structure forming contacts with a contact liner over the top electrodes in accordance with an embodiment of the present invention.

FIG. 19 depicts a cross-sectional view of the semiconductor structure after depositing a different encapsulation material over the semiconductor structure of FIG. 6 in accordance with an embodiment of the present invention.

FIG. 20 depicts a cross-sectional view of the semiconductor structure after forming the encapsulation around the portions of the reference layer, depositing and planarizing a layer of ILD in accordance with an embodiment of the present invention.

FIG. 21 depicts a cross-sectional view of the semiconductor structure after forming the MTJ pillar with the tapered top electrode and the contacts to the top electrode in accordance with an embodiment of the present invention.

### DETAILED DESCRIPTION

Embodiments of the present invention recognize that typical magnetic tunnel junctions (MTJs) can include one or more layers of a cobalt-based synthetic anti-ferromagnet (SAF), a cobalt-iron-boron (CoFeB) based reference layer, a magnesium oxide (MgO) based tunnel layer, CoFeB based free layer, and cap layers containing Ta or ruthenium (Ru) but are not limited to these MTJ. Conventionally formed MTJ stacks in magnetoresistive memory (MRAM) devices are composed of many very thin layers of various magnetic and non-magnetic layers that are sequentially deposited. A directional etch of an MTJ stack can form any number of MTJ pillars. After the directional etch process, an interlayer dielectric material is deposited between the MTJ pillars to form conventional MRAM devices.

Embodiments of the present invention recognize that high-performance MRAM devices with MTJ pillars that are perpendicular to the surface of the semiconductor substrate require well-defined interfaces in the MTJ pillars. Embodiments of the present invention recognize that for optimal MRAM device performance, interface control is essential in the MTJ of MRAM devices.

Embodiments of the present invention recognize that MTJ pillars are typically formed by one or more directional etching processes on a bottom electrode by the patterning and etching of the sequentially deposited layers of the magnetic and non-magnetic materials forming an MTJ stack. Embodiments of the present invention recognize that in conventional MRAM devices, the interlayer dielectric is deposited in a single deposition process to fill the gaps between adjacent MTJ pillars in conventionally formed MRAM devices. As the MRAM devices become more closely packed, the depth of the gap to be filled by the interlayer dielectric increases. As the depth of gap to be filled between adjacent MTJ pillars becomes deeper and more difficult to fill in conventionally formed MRAM devices, voids in the deposited interlayer dielectric material may occur.

An aspect ratio can be defined as a height or depth of a hole or gap over the width of the hole where, in general, a higher aspect ratio hole is harder to fill. In conventionally formed MRAM devices with a decreasing pitch or space between the MRAM devices, the narrow and deeper gap between adjacent MRAM devices formed by the adjacent MTJ pillars increases the aspect ratio of the gap to be filled between adjacent MTJ pillars. As the aspect ratio and the gap depth between adjacent MTJ pillars increases with decreasing MTJ pillar pitch, in conventionally formed MRAM devices, it becomes more challenging to provide a void-free interlayer dielectric between adjacent MTJ pillars. Embodiments of the present invention recognize that voids in the interlayer dielectric between adjacent MTJ pillars are associated with shorts between adjacent MRAM devices after contact formation in MRAM devices.

Embodiments of the present invention recognize that a method of forming MRAM devices without interlayer dielectric voids between adjacent MRAM devices would be desirable. A method of forming MRAM devices without voids in the interlayer dielectric between adjacent MRAM devices could improve MRAM device yield loss due to shorting, especially, between adjacent, closely packed MRAM devices.

Embodiments of the present invention provide a semiconductor structure for MRAM devices with a tapered sidewall and with a layer of void-free interlayer dielectric material abutting each layer of the MTJ pillars in adjacent MRAM devices. Embodiments of the present invention provide a semiconductor structure where each layer of an adjacent MTJ pillar abuts and is separated by a portion of a layer of interlayer dielectric (ILD). Each portion of the layer of ILD material formed between each layer of the MTJ pillars is void-frec.

Embodiments of the present invention provide a void-free portion of a layer of ILD material between each of the adjacent bottom electrodes, reference layers, tunnel barrier layers, free layers, top electrodes, and contacts to the top electrodes of two or more adjacent MTJ pillars. Each layer of ILD material is deposited in a gap between each layer of the MTJ pillar, where each gap to be filled by the ILD material is a thin gap that has a depth that is the same as the portions of each layer of the MTJ pillar material that the ILD material separates (e.g., the depth of the gap for ILD fill is the thickness of the reference layer, the tunnel barrier layer, etc.). In other words, one layer of ILD material is deposited in a gap or recess that has the same depth as the thickness of the bottom electrode, and similarly, another layer of ILD material is deposited in a gap that has a depth that is the same as the thickness of the reference layer of the MTJ pillars. Providing a small deposition depth or a low aspect ratio for ILD gap fill for each layer of the MTJ pillars prevents the formation of voids in the ILD layers between the adjacent MTJ pillars. In general, a lower aspect ratio hole is easier to fill. Embodiments of the present invention present a semiconductor structure with at least two adjacent MTJ pillars separated by portions of multiple layers of void-free ILD material.

Embodiments of the present invention provide a semiconductor structure where each material layer of the MTJ pillar resides on a lower material layer of the MTJ pillar with a different width. Embodiments of the present invention disclose the MTJ pillar with a bottom electrode that is wider than the reference layer that resides on the bottom electrode. Embodiments of the present invention disclose a tunnel barrier layer that is wider than the reference layer and a free layer that is less wide than the tunnel barrier layer. Embodiments of the present invention disclose a tapered top electrode with a bottom surface that is approximately the same width as free layer with an encapsulation material around it and where the top surface of the top electrode is smaller than the bottom surface of the top electrode (i.e., the top electrode has a tapered sidewall creating a cone-like top electrode shape with a flat top and bottom surface). Embodiments of the present invention provide a MTJ pillar with a pagoda-like cross-section

Embodiments of the present invention provide an MTJ pillar with the same dielectric material encapsulating the reference layer and the free layer of each MTJ pillar. Embodiments of the present invention also provide a semiconductor structure with MTJ pillars formed using one dielectric material to encapsulate a sidewall of the reference layer and a second dielectric material to encapsulate the free layer.

Embodiments of the present invention disclose a semiconductor structure and a method of forming the semiconductor structure with a tapered top electrode on each of the MTJ pillars. The tapered top electrode has a top surface that is smaller than the bottom surface of the top electrode. The tapered top electrode creates an upside-down funnel-shaped gap between the adjacent top electrodes to further case the ILD gap fill between the adjacent top electrodes to provide a void-free ILD between the adjacent top electrodes.

Embodiments of the present invention provide a method of forming a semiconductor structure with two adjacent MTJ pillars where each layer of the MTJ pillars and each layer of ILD between each layer of the MTJ pillars are sequentially deposited. Embodiments of the present invention provide a method of forming multiple depositions of ILD during MTJ pillar formation where the depth of the recess between each layer of the adjacent MTJ pillars to be filled by each layer of ILD is very small. In other words, embodiments of the present invention provide a method of depositing and patterning a layer a MTJ pillar material and depositing a layer of ILD over the MTJ pillar layer and in a recess between adjacent portions of the MTJ material where the recess has the same thickness as the layer of the MTJ pillar material.

Embodiments of the present invention provide a method of forming the semiconductor structure where each layer of the MTJ pillar is independently deposited and patterned. A deposition of layer of ILD occurs after patterning each layer of the MTJ pillar. Furthermore, the method includes forming a sidewall encapsulant around each portion of the reference layer and around the portions of the free layer, where the dielectric material of the encapsulation may be the same dielectric material around the reference layer and the free layer or a different dielectric material.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for the purposed pf illustration only and not for the purpose of limiting the invention as defined by the appended claims and their equivalents.

It is to be understood that the singular forms “a,” “an,” and “the” include plural referents unless the context dictates otherwise. Thus, for example, reference to “a component surface” includes reference to one or more of such surfaces unless the context dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

Deposition processes for metal materials and sacrificial materials include, e.g., chemical vapor deposition (CVD), physical vapor deposition (PVD), atomic layer deposition (ALD), or gas cluster ion beam (GCIB) deposition. CVD is a deposition process in which a deposited species is formed as a result of a chemical reaction between gaseous reactants at greater than room temperature (e.g., from about 25 C to about 900 C.). The solid product of the reaction is deposited on the surface on which a film, coating, or layer of the solid product is to be formed. Variations of CVD processes include, but are not limited to, atmospheric pressure CVD (APCVD), low-pressure CVD (LPCVD), plasma enhanced CVD (PECVD), and metal-organic CVD (MOCVD), and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use gas cluster ion beams (GCIB) deposition, the high-pressure gas is allowed to expand in a vacuum, subsequently condensing into clusters. The clusters can be ionized and directed onto a surface, providing a highly anisotropic deposition.

Selectively etching as used herein includes but is not limited to patterning using one of lithography, photolithography, an extreme ultraviolet (EUV) lithography process, or any other known semiconductor patterning process followed by one or more etching processes. Various materials are referred to herein as being removed or “etched” whereas etching generally refers to one or more processes implementing the removal of one or more materials while leaving other protected areas of the materials that are masked during the lithography processes unaffected. Some examples of etching processes include but are not limited to the following processes, such as a dry etching process using a reactive ion etch (RIE) or ion beam etch (IBE), a wet chemical etch process, or a combination of these etching processes. A dry etch may be performed using plasma. Ion milling, sputter etching, or reactive ion etching (RIE) bombards the wafer with energetic ions of noble gases that approach the wafer approximately from one direction, and therefore, these processes are an anisotropic or a directional etching process.

As known by one skilled in the art, damascene processes for forming circuit lines and/or contacts typically include various steps of patterning via holes and trenches in a dielectric material, such as an interlayer dielectric and filling the via holes and trenches with a layer of metal and planarizing the metal using a chemical mechanical process such as a chemical-mechanical polish (CMP) to remove overburden or excess metal.

References in the specification to “one embodiment”, “other embodiment”, “another embodiment”, “an embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

FIG. 1 depicts a cross-sectional view of semiconductor structure 100 after forming metal cap 6 on metal pad 5 with liner 4 in interlayer dielectric (ILD) 3 in accordance with an embodiment of the present invention. As depicted, FIG. 1 includes metal pad 5, liner 4, metal cap 6, dielectric cap 7, and ILD 3 where metal pad 5 may be a contact, a pad, or a portion of a wire, or metal layer in a middle-of-line (MOL) or back end of line (BEOL) semiconductor layer. In various embodiments, one or more front end of the line (FEOL) semiconductor devices reside below metal pad 5. In one embodiment, metal pad 5 is a contact in or to a FEOL semiconductor device. Metal pad 5 may be composed of any known metal contact or wiring material for semiconductor devices, such as MRAMs. For example, metal pad 5 may be composed of any known metal materials, such as, but not limited to, tungsten (W), copper (Cu), cobalt (Co), or ruthenium (Ru).

Liner 4 can be composed of a metal nitride material, a pure metal material, or a combination of layers of one or more of these materials. For example, liner 4 may be composed of but not limited to one or more metal materials, such as tantalum (Ta), titanium (Ti), or metal nitride materials, such as tungsten-nitrogen alloys (e.g., WN), hafnium-nitride alloys (e.g., HfN), titanium-nitrogen alloys, tantalum-nitrogen alloys (e.g., TaN), titanium-aluminum-nitrogen alloys, or tantalum-aluminum-nitrogen alloys.

In various embodiments, liner 4 under and around metal pad 5 may be titanium (Ti) or titanium nitride (TiN) when metal pad 5 is composed of tungsten (W). In other examples, liner 4 may be tantalum (Ta) or tantalum nitride (TaN) when metal pad 5 is composed of copper (Cu). Metal pad 5 and liner 4 are not limited to these materials.

In various embodiments, metal cap 6 resides over metal pad 5 and may be composed of but not limited to TiN or WN. Dielectric cap 7 may be any material used as a dielectric cap material in MRAM devices, such as but not limited to silicon nitride (SiN).

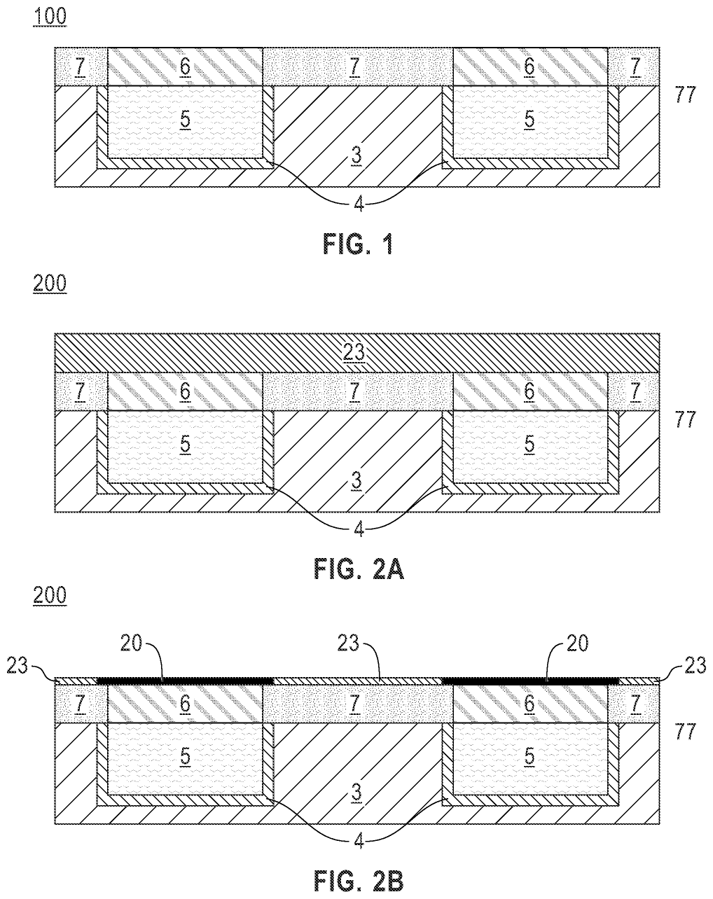

FIG. 2A depicts a cross-sectional view of semiconductor structure 200A after depositing and patterning ILD 23 over metal cap 6 and dielectric cap 7 in accordance with an embodiment of the present invention. As depicted, FIG. 2A includes metal pad 5, liner 4, metal cap 6, dielectric cap 7, ILD 3, and ILD 23 over a portion of dielectric cap 7 and metal cap 6. ILD 23 may be deposited with any known ILD deposition process (e.g., CVD, PVD, etc.) over metal cap 6 and dielectric cap 7 and planarized by CMP. In various embodiments, ILD 23 is composed of a SiOC-based dielectric material (e.g., SiCOH or SiCNO) but is not limited to these dielectric materials.

FIG. 2B depicts a cross-sectional view of semiconductor structure 200B after forming bottom electrode 20 in accordance with an embodiment of the present invention. As depicted, FIG. 2B includes the elements of FIG. 2A and bottom electrode 20. Using known damascene processes, bottom electrode 20 may be formed using the deposition of any known MRAM device electrode material. ILD 23 may be patterned, for example using lithography and a suitable wet or dry etching process (e.g., RIE) to remove portions of ILD 23 over metal cap 6 and adjacent portions of dielectric cap 7. Bottom electrode 20 may be composed of one or more electrode materials such as titanium (Ti), tungsten (W), molybdenum (Mo), or a metal nitride (e.g., TiN or MON).

In various embodiments, a CMP planarizes the top surface of the deposited electrode material and removes a portion of ILD 23. After the planarization of the exposed top surfaces of ILD 23 and the electrode material for bottom electrode 20, the thickness of bottom electrode 20 may range from 2 nm to 50 nm but is not limited to this range. A thin layer of ILD 23 with the same thickness of bottom electrode 20 remains between the two adjacent bottom electrodes 20 as depicted in FIG. 2B.

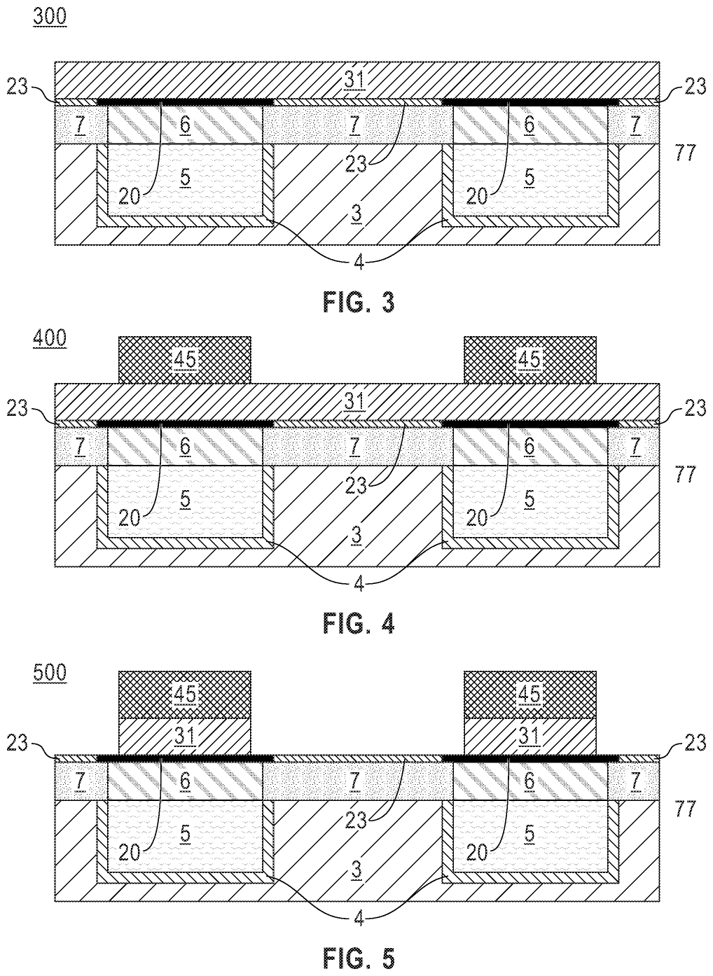

FIG. 3 depicts a cross-sectional view of semiconductor structure 300 after depositing reference layer 31 of the magnetic tunnel junction (MTJ) over bottom electrode 20 and ILD 23 in accordance with an embodiment of the present invention. As depicted, FIG. 3 includes the elements of FIG. 2B and reference layer 31. Using known deposition processes for a reference layer (e.g., CVD or PVD), reference layer 31 is deposited on bottom electrode 20 and ILD 23. For example, reference layer 31 could be a cobalt-iron-boron (CoFeB) based reference layer material or any other suitable material for an MTJ reference layer.

FIG. 4 depicts a cross-sectional view of semiconductor structure 400 after depositing and patterning a layer of hardmask 45 on reference layer 31 in accordance with an embodiment of the present invention. As depicted, FIG. 4 includes the elements of FIG. 3 and the remaining portions of the patterned hardmask 45. After patterning hardmask 45, the remaining portions of hardmask 45 reside on reference layer 31 above bottom electrode 20. Hardmask 45 may be composed of SiN, TIN, TaN, a photoresist, or any other known hardmask material. As depicted, the remaining portions of hardmask 45 have a horizontal width that is less than the width of bottom electrode 20.

FIG. 5 depicts a cross-sectional view of semiconductor structure 500 after etching exposed portions of reference layer 31 in accordance with an embodiment of the present invention. As depicted, FIG. 5 includes the elements of FIG. 4 without the exposed portions of reference layer 31. For example, using the remaining portions of hardmask 45 as an etch mask, the exposed horizontal portions of reference layer 31 may be removed (e.g., by RIE) over ILD 23 and over a portion of bottom electrode 20, as depicted in FIG. 5.

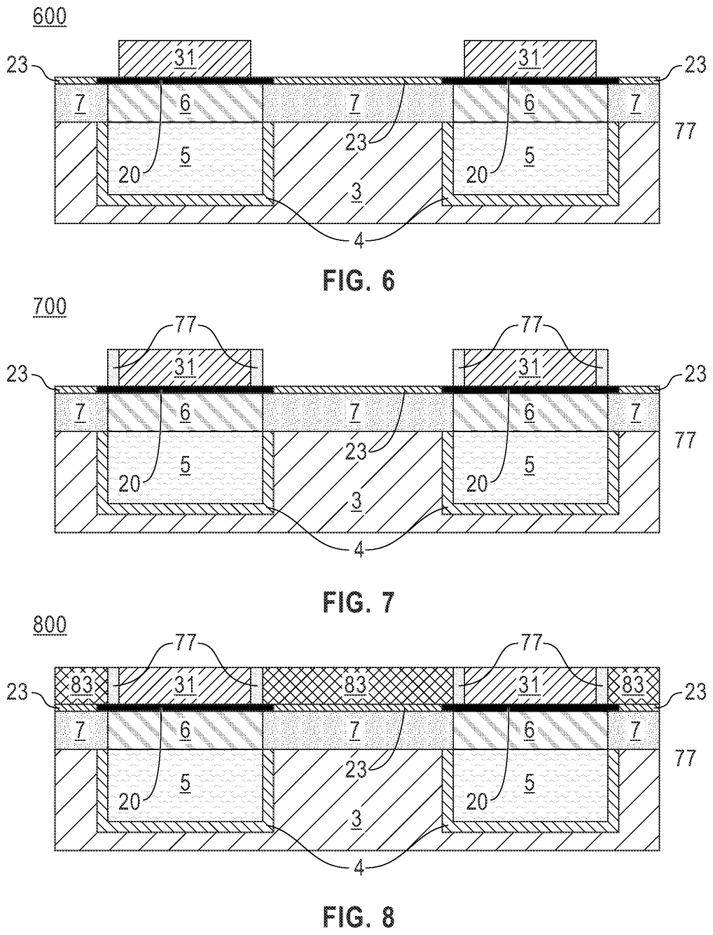

FIG. 6 depicts a cross-sectional view of semiconductor structure 600 after removing the portions of hardmask 45 in accordance with an embodiment of the present invention. As depicted, FIG. 6 includes ILD 3, liner 4, metal pad 5, metal cap 6, dielectric cap 7, bottom electrode 20, ILD 23, and reference layer 31 over a portion of bottom electrode 20. After etching hardmask 45, the remaining portion of reference layer 31 is less wide than the width of bottom electrode 20. In one embodiment, reference layer 31 has approximately the same width as bottom electrode 20.

FIG. 7 depicts a cross-sectional view of the semiconductor structure after depositing a layer of encapsulation 77 and etching back encapsulation 77 in accordance with an embodiment of the present invention. As depicted, FIG. 7 includes the elements of FIG. 6 and encapsulation 77. In various embodiments, a layer of dielectric material for encapsulating the sidewalls of reference layer 31 is deposited over the exposed surfaces of ILD 23, bottom electrode 20, and reference layer 31. For example, using one of ALD, CVD, or PVD, a layer of an encapsulant dielectric material such as SiN or SiNC may be deposited as encapsulation 77 but another dielectric material may be used to encapsulate reference layer 31 in other embodiments of the present invention. Using a directional etching process (e.g., RIE and/or IBE), the horizontal portions of the deposited dielectric material can be removed to form encapsulation 77 around the sidewall of reference layer 31. As known to one skilled in the art, encapsulation 77 may also be known as a sidewall spacer or spacer. As depicted in FIG. 7, encapsulation 77 covers the sidewall of reference layer 31. As depicted in FIG. 7, the width of reference layer 31 with encapsulation 77 is greater than the width of bottom electrode 20.

FIG. 8 depicts a cross-sectional view of the semiconductor structure after depositing ILD 83 around and over encapsulation 77, on the top surface of reference layer 31, and over ILD 23 and performing a CMP in accordance with an embodiment of the present invention. As depicted, FIG. 8 includes the elements of FIG. 7 and ILD 83. ILD 83 fills the gap between adjacent portions of encapsulation 77 surrounding the sidewall of adjacent portions of reference layer 31.

The gap between the adjacent portions of reference layer 31 with vertical sides covered by encapsulation 77 provides a low aspect ratio gap for the gap fill using ILD 83. The low aspect ratio for the gap fill is due to the relatively low height (e.g., in the range of 2 to 50 nm or more) of adjacent portions of reference layer 31 with sidewall encapsulation 77 and the relatively larger width of the space between the adjacent portions of reference layer 31. With a small gap height between adjacent reference layer 31 to be filled by ILD 83, the gap between encapsulation 77 on adjacent portions of reference layer 31 can be filled without voids.

ILD 83 can be composed of the same ILD material as ILD 23 or may be composed of any other suitable ILD material. For example, ILD 83 may be composed of SICOH and ILD 23 may be composed of SiCNO or another dielectric material.

After depositing ILD 83, a CMP can planarize the top surface of semiconductor structure 800. The planarization removes ILD 83 from the top surface of reference layer 31.

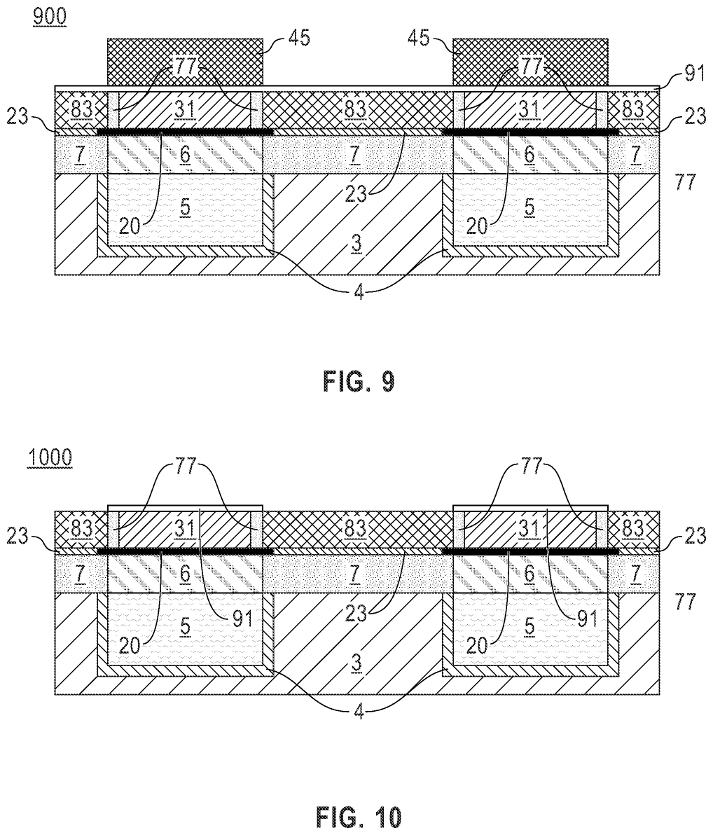

FIG. 9 depicts a cross-sectional view of semiconductor structure 900 after depositing tunnel barrier layer 91 and patterning hardmask 45 on tunnel barrier layer 91 in accordance with an embodiment of the present invention. As depicted, FIG. 9 includes the elements of FIG. 8 and deposited tunnel barrier layer 91 with a patterned layer of hardmask 45. Typically, tunnel barrier layer 91 is a very thin layer of a non-magnetic tunnel barrier layer such as magnesium oxide (MgO). For example, tunnel barrier layer 91 can be five to fifteen angstroms thick and may be composed of one or more layers of material.

In various embodiments, a layer of hardmask 45 is deposited on tunnel barrier layer 91 and planarized. Hardmask 45 can be the same hardmask material previously deposited in FIG. 4 or another known hardmask material used in patterning during semiconductor device formation. After patterning (e.g., lithography and etch), the remaining portions hardmask 45 are wider than the portions of reference layer 31 on which tunnel barrier layer 91 resides. In semiconductor structure 900, the width of hardmask 45 after patterning is approximately the same as the width of encapsulation 77 surrounding reference layer 31.

FIG. 10 depicts a cross-sectional view of semiconductor structure 1000 after removing exposed portions of tunnel barrier layer 91 and removing hardmask 45 in accordance with an embodiment of the present invention. As depicted, FIG. 10 includes the elements of FIG. 9 without hardmask 45 and without exposed portions of tunnel barrier layer 91. The portions of tunnel barrier layer 91 not covered by hardmask 45 are removed during the etching process (e.g., RIE). The remaining portions of tunnel barrier layer 91 after etching are wider than the portions of reference layer 31. As depicted, the remaining portions of tunnel barrier layer 91 cover the exposed surfaces of encapsulation 77 and reference layer 31. In some cases (not depicted), tunnel barrier layer 91 extends beyond encapsulation 77 to cover a portion of ILD 83. Reference layer 31 is less wide than tunnel barrier layer 91.

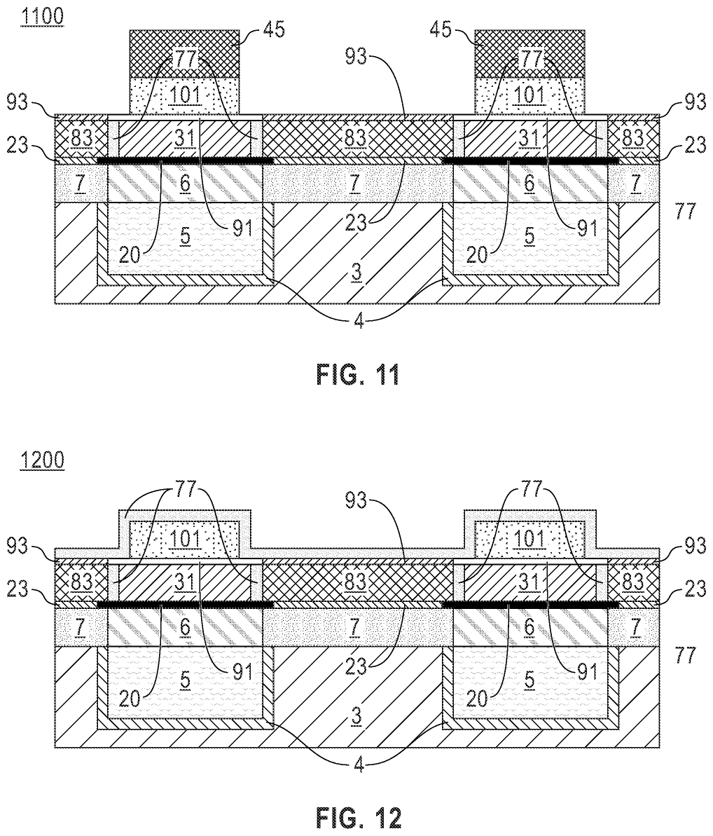

FIG. 11 depicts a cross-sectional view of semiconductor structure after depositing ILD 93, removing excess ILD 93 on tunnel barrier layer 91, depositing and patterning free layer 101 using a patterned hardmask 45 in accordance with an embodiment of the present invention. As depicted, FIG. 11 includes the elements of FIG. 10 and ILD 93 between the remaining portions of tunnel barrier layer 91, free layer 101, and hardmask 45.

In various embodiments, a layer of ILD 93 is deposited over tunnel barrier layer 91 and ILD 83. A CMP planarizes the top surface of ILD 93 to expose the top surface of the remaining portions of tunnel barrier layer 91. After planarizing ILD 93, a layer of free layer 101 is deposited over exposed portions of tunnel barrier layer 91 and ILD 93 using known deposition processes (e.g., CVD, PVD, ALD, etc.). Hardmask 45 is deposited and patterned on free layer 101. Hardmask 45 may be composed of the same material as hardmask 45 deposited in FIGS. 4 and 9 or in other examples, may be composed of another known hardmask material. After patterning, the width of the remaining portions of hardmask 45 is smaller than the width of the remaining portions of tunnel barrier layer 91.

After or in some cases, during patterning of hardmask 45, the exposed portions of free layer 101 can be removed, for example, by RIE. As depicted in FIG. 11, the remaining portions of free layer 101 on tunnel barrier layer 91 are less wide than the portions of tunnel barrier layer 91. In this way, using the process steps and semiconductor structures as depicted in FIGS. 3-11, a tapered MTJ pillar is being formed. By sequentially depositing and individually etching each layer of material forming the MTJ pillar where, in general, with the exception of tunnel barrier layer 91, each patterned layer of the MTJ pillar is less wide than the layer of MTJ material on which it is deposited. As depicted in FIG. 11, the non-magnetic tunnel barrier layer 91 separates the portions of reference layer 31 from the portions of free layer 101 for MTJ functionality.

FIG. 12 depicts a top view of semiconductor structure 1200 after depositing a layer of encapsulation 77 in accordance with an embodiment of the present invention. As depicted, FIG. 12 includes the elements of FIG. 11 and a layer of encapsulation 77 over the top surface of semiconductor structure 1200. In various embodiments, encapsulation 77 on free layer 101 is composed of the same material as encapsulation 77 around the sidewall of reference layer 91. For example, encapsulation 77 can be composed of SiN or SiNC but is not limited to these materials. Encapsulation 77 may be deposited with known deposition processes such as ALD or CVD on the exposed surfaces of ILD 93, tunnel barrier layer 91, and free layer 101.

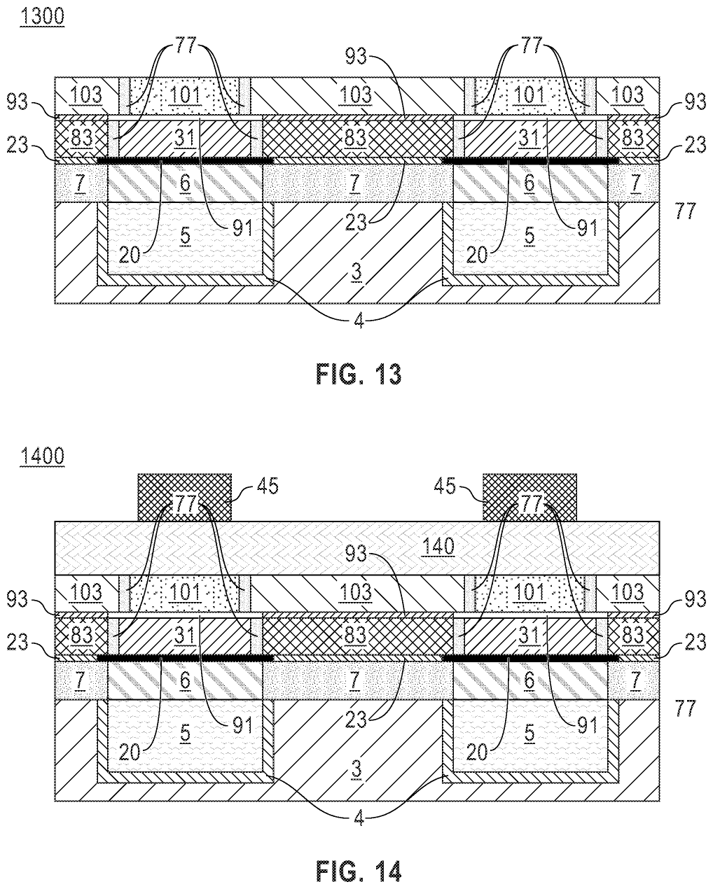

FIG. 13 depicts a cross-sectional view of semiconductor structure 1300 after etching the horizontal portions of encapsulation 77, depositing a layer of ILD 103, and performing a CMP in accordance with an embodiment of the present invention. As depicted, FIG. 13 includes the elements of FIG. 12 with ILD 103 and without the horizontal portions of encapsulation 77.

In various embodiments, a directional etching process removes the horizontal portions of encapsulation 77. The vertical portions of encapsulation 77 remain on the sidewall of free layer 101. As depicted, tunnel barrier layer 91 is wider than the width of free layer 101 with encapsulation 77 but tunnel barrier layer 91 is not limited to this width (e.g., may be the same with as encapsulation 77 on free layer 101 but may not be less wide than free layer 101).

A layer of ILD 103 is deposited over the exposed surfaces of ILD 93, tunnel barrier layer 91, encapsulant 77, and free layer 101. The deposition of ILD 103 fills the gap between each portion of encapsulation 77 on the sidewalls of the portions of free layer 101. The depth of the gap to be filled by ILD 103 corresponds to the thickness of free layer 101. The gap depth between adjacent portions of free layer 101 provides a low aspect ratio hole or gap for ILD gap fill that is easily filled without creating voids in ILD 103. Similar to ILD 23, ILD 83, and ILD 93, ILD 103 may be deposited by CVD or PECVD but is not limited to these deposition processes. ILD 103 may be composed of a different dielectric material or the same dielectric material as any or all of ILD 23, ILD 83, and ILD 93. A CMP can remove the excess portions of ILD 103 and exposes the top surface of free layer 101.

FIG. 14 depicts a cross-sectional view of semiconductor structure 1400 after depositing a layer of electrode material for top electrode 140, depositing and patterning hardmask 45 in accordance with another embodiment of the present invention. As depicted, FIG. 14 includes the elements of FIG. 13 and a layer of top electrode material for top electrode 140 and hardmask 45.

In various embodiments, a layer of top electrode material for top electrode 140 is deposited over the exposed surfaces of ILD 103, encapsulation 77, and free layer 101. Similar to bottom electrode 20, the layer of material for top electrode 140 can be composed of a metal such as Ti, Mo, W, or a metal nitride such as TiN or MoN but is not limited to these materials. In various embodiments, top electrode 140 is deposited by one or more of PVD, CVD, or ALD but the deposition is not limited to these processes.

Using previously described processes and materials for hardmask 45 deposition and patterning, portions of hardmask 45 are etched, and the remaining portions of patterned hardmask 45 reside on top electrode 140. The remaining portions of hardmask 45 have a width that is less than the width of free layer 101.

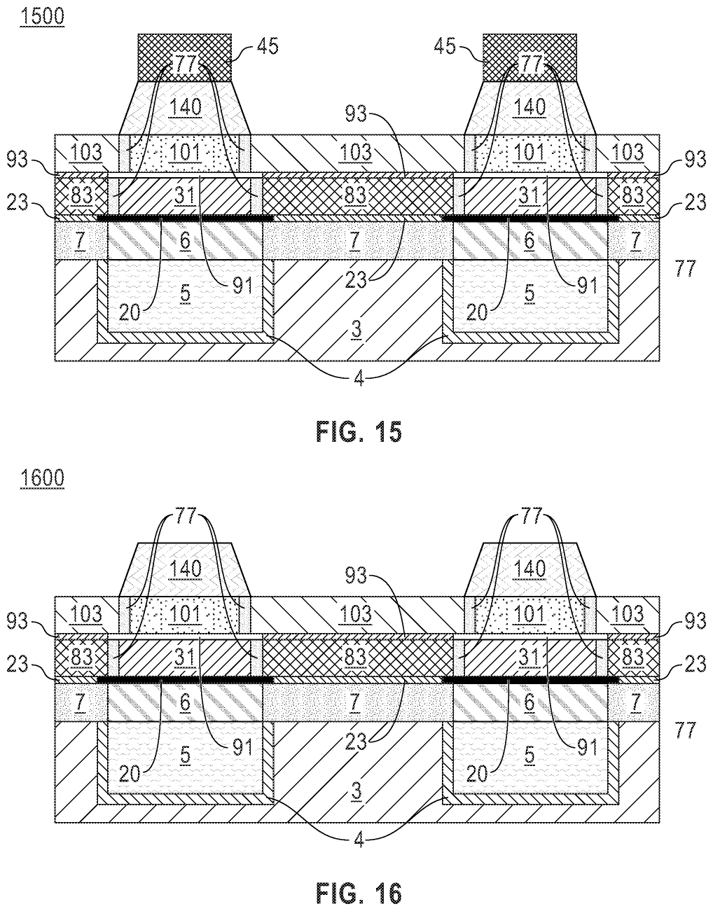

FIG. 15 depicts a cross-sectional view of semiconductor structure 1500 after removing portions of top electrode 140 in accordance with an embodiment of the present invention. As depicted, FIG. 15 includes the elements of FIG. 14 without the exposed portions of top electrode 140.

In various embodiments, an angled directional etching process removes a larger portion of top electrode 140 under hardmask 45. For example, using an angled IBE, the sidewall of top electrode 140 is tapered with a smaller top surface of top electrode 140 directly under hardmask 45 and a larger bottom surface of top electrode 140 directly on free layer 101 and encapsulation 77. After the angled directional etching process, top electrode 140 has a cone shape with a narrower top surface and a wider bottom surface. The sidewalls of top electrode 140 are sloped or tapered forming a cone shape with a flat top and bottom surface. The width of the bottom surface of top electrode 140 is approximately the same width as the top surface of free layer 101 and encapsulant 77 around free layer 101. As depicted, the cross-section of top electrode 140 has a trapezoidal shape. As depicted in FIG. 15, the sidewall of top electrode 140 can be formed with an angle greater than 90 degrees (e.g., an obtuse angle) to the exposed horizontal surface of ILD 103. The tapering of top electrode 140 will further improve the gap fill for the ILD deposited later as depicted in FIG. 16.

FIG. 16 depicts a cross-sectional view of semiconductor structure 1600 after removing hardmask 45 in accordance with an embodiment of the present invention. As depicted, FIG. 16 includes ILD 3, metal pad 5, liner 4, metal cap 6, dielectric cap 7, ILD 23, bottom electrode 20, reference layer 31, encapsulation 77 around the sidewall of reference layer 31, ILD 83, tunnel barrier layer 91, ILD 93, ILD 103, encapsulation 77 around the sidewall of free layer 101, and top electrode 140. Using known etching wet or dry etching processes, hardmask 45 is removed from the top surface of top electrode 140.

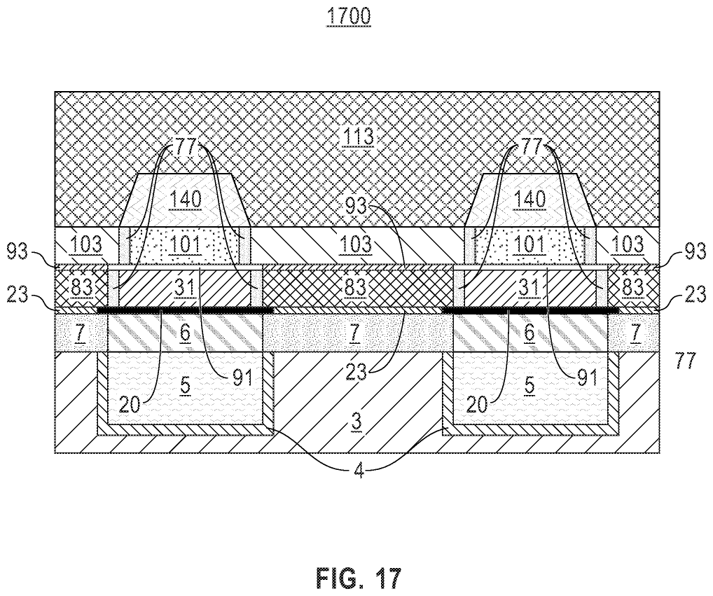

FIG. 17 depicts a cross-sectional view of the semiconductor structure after depositing a layer of ILD 113 over top electrode 140 and ILD 103 in accordance with an embodiment of the present invention. As depicted, FIG. 17 includes the elements of FIG. 16 and ILD 113. ILD 113 can be the same ILD material as one or more of ILD 23, 83, 93, or 103 or may be another ILD material. For example, ILD 113 can be a SiOC-based material deposited by CVD or PECVD but is not limited to these materials and processes. The gap fill between adjacent top electrode 140 is a low aspect ratio gap fill. ILD 133 completely fills the recesses or gaps between the remaining portions of the tapered top electrode 140. The depth of the gap fill is the thickness of top electrode 140. The ability to fill the gap between adjacent top electrode 140 without voids is further enhanced by the tapered sidewall of top electrode 140. After the angled directional process to form top electrode 140 creates a top surface and top portion of top electrode 140 that is narrower than the bottom portion of top electrode 140. The less wide top surface and top portion of top electrode 140 creates a wider gap near the top of top electrode 140. The gap decreases as the gap approaches the bottom portion of top electrode 140 adjacent to the top surface of ILD 103. As depicted in semiconductor structure, ILD 113 can be void-free as deposited by CVD or PECVD over ILD 103 between and over top electrode 140. ILD 113 can be deposited with a thickness sufficient for later contact formation on top electrode 140 in ILD 113.

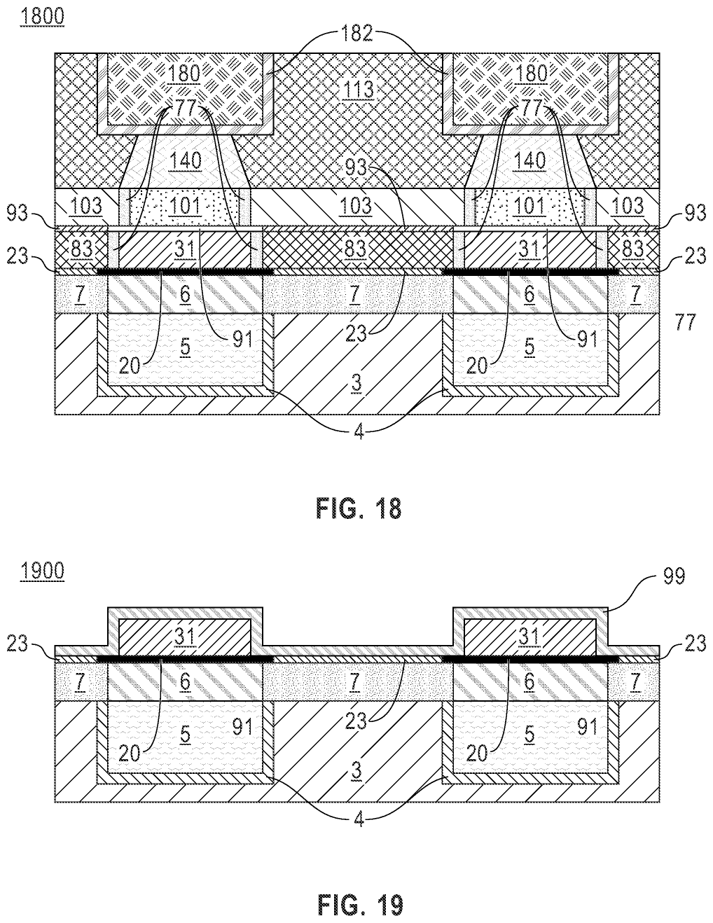

FIG. 18 depicts a cross-sectional view of semiconductor structure 1800 after forming contacts 180 with contact liner 182 over top electrode 140 in accordance with an embodiment of the present invention. As depicted, FIG. 18 includes contacts 180 with contact liner 182 in ILD 113, top electrode 140, ILD 103, encapsulation 77 around the sidewall of free layer 101, ILD 93, tunnel barrier layer 91, ILD 83, encapsulation 77, around reference layer 31, ILD 23, bottom electrode 20, metal cap 6, dielectric cap 7, ILD 3, and metal pad 5 with liner 4.

With known back end of line (BEOL) or middle of the line (MOL) contact formation processes, such as damascene processes (e.g., patterning, etching contact holes, metal deposition, CMP), metal contacts 180 with contact liner 182 can be formed. The contact material can be any of the materials used for metal pad 5 but is not limited to these materials. For example, when contact liner 182 is composed of Ti or TiN, then, typically contact 180 would be composed of W. Similarly, when contact liner 182 is composed of Ta or TaN, then, contact 180 would be composed of Cu. A CMP removes excess material from contact 180 and contact liner 182 over ILD 113 to form contacts 180 on top electrode 140.

As depicted in FIG. 18, ILD 113, ILD 103, ILD 93, ILD 83, and ILD 23 are void-free as each layer of ILD in semiconductor structure 1800 is deposited individually. Each layer of ILD 113, ILD 103, ILD 93, ILD 83, and ILD 23 are deposited in low aspect ratio gaps between a single layer of the MTJ (e.g., between encapsulation 77 or sidewall spacers around each of reference layer 31, tunnel barrier layer 91 (no encapsulation), free layer 101, and between bottom electrode 20 and top electrode 140. Individually depositing each layer of ILD in shallow gaps between the various layers of the MTJ to form the MTJ pillar of the MRAM device prevents the formation of ILD voids that can result in shorting between contacts 180 and/or top electrode 140. As a result of reducing ILD voids between the upper regions of adjacent MTJ pillars (e.g., contacts 180, top electrode 140, and free layer 101), the shorting of adjacent MRAM devices, particularly in densely packed regions of MRAM devices in the resulting semiconductor chip can be reduced.

In various embodiments, semiconductor structure 1800 has a layer of ILD deposited around each layer of sequentially deposited material of the MTJ. In this way, semiconductor structure 1800 has as many layers of ILD as the layers of the MTJ. As depicted in FIG. 18, ILD 23 surrounds bottom electrode 20, ILD 83 abuts a sidewall spacer of reference layer 31 labeled as encapsulation 77, ILD 93 abuts the sidewall of tunnel barrier layer 91, ILD 103 abuts the sidewall spacer of free layer 101 labeled as encapsulation 77, and ILD 113 abuts top electrode 140. Each portion of ILD 23, 83, 93, 103, and 113 as depicted in FIG. 18 separate at least two adjacent MTJ pillars and each of the portions of ILD 23, 83, 93, 103, and 113 are essentially void-free and deposited in a relatively thin or shallow gap between the layers of the adjacent MTJ pillars. While FIG. 18 depicts two adjacent MTJ pillars, as known to one skilled in the art, each MTJ pillar may be directly adjacent to two or more other MTJ pillars.

Additionally, semiconductor structure 1800 provides increasing gap widths resulting in wider layers of ILD associated with ascending layers of ILD in the MTJ pillar. As depicted in FIG. 18, the width of ILD 103 adjacent to top electrode 140 is greater than the width of ILD 103 adjacent to free layer 101, the width of ILD 93 adjacent to tunnel barrier layer 91 is a very thin layer of ILD that is approximately the same width as the width of ILD 83 adjacent to reference layer 31, and the width of ILD 83 is greater than the width of ILD 23 around bottom electrode 20. Furthermore, the tapered shape of top electrode 140 also aids in the void-free layer of ILD 113 after ILD 113 deposition. The void-free deposition of ILD 113 abutting top electrode 140 and contacts 180 is especially advantageous for reducing shorts between adjacent MTJ pillars in densely packed MRAM devices.

The increasing width of each sequential layer of ILD deposited on a portion of the previously deposited ILD is enabled by a decreasing width of each additionally deposited magnetic layer of the MTJ. Tunnel barrier layer 91 which is the very thin, non-magnetic material layer of the MTJ pillar, is approximately the same width as the encapsulated reference layer 31. In FIG. 18, bottom electrode 20 is wider than reference layer 31, tunnel barrier layer 91 is wider than free layer 101, reference layer 31 is also wider than free layer 101, and as previously stated, the thin, non-magnetic tunnel barrier layer 91 is approximately the same width as encapsulation 77 around reference layer 31.

In semiconductor structure 1800, encapsulation 77 surrounding reference layer 31 and free layer 101 is depicted as being composed of the same encapsulant material. The resulting MTJ pillar with the tapered top electrode 140 and different widths that are generally wider in the descending layers of the MTJ pillar results in a pagoda-like profile or pagoda-like cross-sectional pagoda like shape of the MTJ pillar cross-section depicted in semiconductor structure 1800. While embodiments of the present invention specifically discuss an MTJ pillar composed of reference layer 31 on bottom electrode 20 with tunnel barrier layer 91 above reference layer 31 and free layer 101 under top electrode 140 and on tunnel barrier layer 91, as known to one skilled in the art, MRAM devices with MTJ pillars can be formed with more or other layers of magnetic and non-magnetic materials layers using the same or similar processes and steps as discussed with reference to FIGS. 1-18 to provide layers of void-free ILD between adjacent MRAM devices.

Additionally, the steps and processes depicted in FIGS. 1-18 can be applied to form semiconductor structures for any other suitable type of semiconductor device (e.g., field-effect transistors, phase-change memory devices, etc.). The steps disclosed herein can be used to create semiconductor structures with elements that decrease in width as the elements are formed above another element and with a layer of dielectric material between the elements in each layer of the semiconductor structure where each element is formed with a layer of dielectric material or ILD that isolates elements of that layer of the semiconductor structure from a layer of an adjacent semiconductor device. In other words, the semiconductor structure is formed with elements or layers that are each separated by portions of an individually deposited dielectric layer (e.g., a five-layer semiconductor device structure would have five layers of dielectric material that are each void-free). Similarly, the semiconductor structure of a vertical element like a pillar (e.g., other stacked memory devices or other stacked logic devices such as stacked CMOS field-effect transistor devices) with each layer of the pillar having a different width than the layer of material it resides on.

In various embodiments, ILD 23, ILD 83, ILD 92, ILD 103, and ILD 113 are composed of the same dielectric material. In some embodiments, some of ILD 23, ILD 83, ILD 93, ILD 103, and ILD 113 are composed of different dielectric materials (e.g., ILD 83, ILD 93, and ILD 103 are composed of the same dielectric material, and ILD 23 and ILD 113 are composed of different dielectric material).

FIG. 19 depicts a cross-sectional view of semiconductor structure 1900 after depositing encapsulation 99 over semiconductor structure 600 of FIG. 6 in accordance with an embodiment of the present invention. As depicted, FIG. 19 includes ILD 3, metal pad 5 with liner 4, metal cap 6, dielectric cap 7, bottom electrode 20, ILD 23, reference layer 31, and encapsulation 99. The elements of FIG. 19 may be formed by essentially processes and except for encapsulation 99, essentially the same materials as previously discussed with respect to FIGS. 1-6.

In various embodiments, encapsulation 99 is composed of a different dielectric material than encapsulation 77. For example, encapsulation 99 can be titanium dioxide (TiO₂), an oxynitride-based material such as SiON, or another dielectric material, including metal oxynitrides such as TION. As depicted in FIG. 19, encapsulation 99 is deposited, for example, by ALD or CVD, over the exposed surfaces of ILD 23, bottom electrode 20, and reference layer 31.

As depicted in FIG. 19, the method of forming semiconductor structure 1900 with a different dielectric material for encapsulation 99 provides flexibility for using a different encapsulation material with different electrical properties around reference layer 31 than the dielectric material of encapsulation 77 that will surround free layer 101 (as depicted later in FIG. 21). In the conventionally formed MRAM devices, using a single deposition process for the encapsulation material around the MTJ pillar, only one encapsulant material can be deposited over and around the completed MTJ pillar after the MTJ stack is etched to form the MTJ pillar. Therefore, in conventionally formed MRAM devices, both the reference layer and the free layer have the same dielectric material forming the sidewall encapsulation.

Using different dielectric materials such as encapsulation 99 and encapsulation 77 to encapsulate reference layer 31 and free layer 101 provides additional design and electrical performance tradeoffs that are not possible with conventionally formed MTJ MRAM devices. For example, depositing a low k dielectric material as encapsulation 99 can reduce the capacitance of reference layer 31.

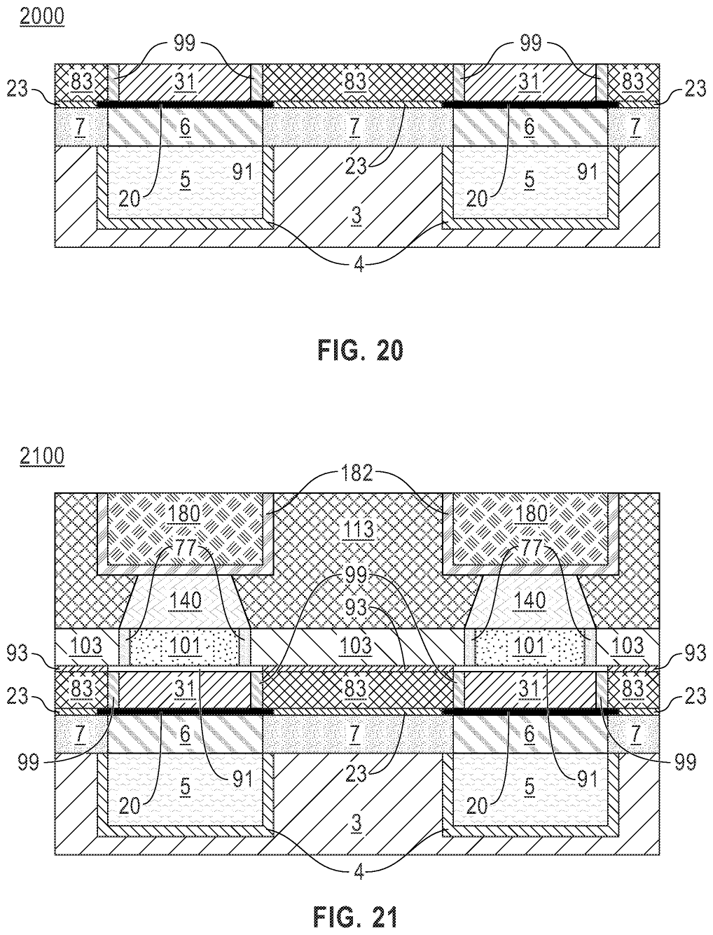

FIG. 20 depicts a cross-sectional view of the semiconductor structure after removing portions of the layer of encapsulation 99, depositing and planarizing the layer of ILD 83 in accordance with an embodiment of the present invention. As depicted, FIG. 20 includes the elements depicted in FIG. 19 with portions of encapsulation 99 and ILD 83 between the remaining portions of encapsulation 99.

For example, using a directional etching process (e.g., RIE), the horizontal portions of encapsulation 99 are removed. The remaining portions of encapsulation 99 surround the sidewall of reference layer 31.

Using one of CVD, PVD, ALD, or another known dielectric deposition process, a layer of ILD 83 is deposited over the exposed surfaces of reference layer 31, ILD 23, bottom electrode 20, and encapsulation 99. ILD 83 fills the gap between portions of encapsulation 99 around the sidewall of the adjacent remaining portions of reference layer 31. As previously discussed, only a low aspect ratio gap fill is needed in semiconductor structure 2000 as the height of the gap is the same as the height of reference layer 31. Due to the low aspect ratio of ILD 83 gap fill, as depicted in FIG. 20, no ILD voids are formed in ILD 83. A CMP planarizes the top surface of semiconductor structure 2000 and exposes the top surface of reference layer 31.

FIG. 21 depicts a cross-sectional view of semiconductor structure 2100 after forming top electrode 140 and contacts 180 with contact liner 182 in accordance with an embodiment of the present invention. As depicted, FIG. 21 includes contacts 180 with contact liner 182 in ILD 113, top electrode 140, ILD 103, encapsulation 77 around free layer 101, ILD 93, tunnel barrier layer 91, ILD 83, encapsulation 99 around reference layer 31, ILD 23, bottom electrode 20, metal cap 6, dielectric cap 7, metal pad 5 with liner 4, and ILD 3. Similar to semiconductor structure 1800, each of ILD 23, ILD 83, ILD 93, ILD 103, and ILD 113 are void-frec.

For example, semiconductor structure 2100 can be formed using the processes and materials as discussed previously in detail with respect to FIGS. 14-18. As previously discussed, a layer of hardmask 45 can be deposited and patterned for a etch mask. Hardmask 45 can be used during the directional etching process (e.g., an angled IBE) to form the tapered shape of top electrode 140. Hardmask 45 can be removed and a layer of ILD 113 deposited over top electrode 140 and ILD 103. Using known damascene processes for contact formation with a liner, contacts 180 with contact liner 182 can be formed in ILD 113 as depicted in FIG. 21.

In various embodiments, semiconductor structure 2100 is formed with essentially the same processes as semiconductor structure 1800. Semiconductor structure 2100 may be formed with uses any of materials discussed with respect to semiconductor structure 1800 with the exception of the sidewall encapsulant material for encapsulation 99 around reference layer 31 which is a different dielectric material than encapsulant 77. In various embodiments, semiconductor structure 2100 uses encapsulation 99 around the sidewall of reference layer 91 includes different dielectric material for encapsulation 77 around the sidewall of free layer 31.

As previously discussed with reference to FIG. 18, semiconductor structure 2100 provides multiple layers of ILD material where an ILD layer is deposited over each remaining portion of bottom electrode 20, reference layer 31, tunnel barrier layer 91, free layer 101, and top electrode 140. ILD 23, ILD 83, ILD 93, ILD 103, and ILD 133 abut bottom electrode 20, encapsulation 99 around reference layer 31, tunnel barrier layer 91, encapsulation 77 around free layer 101, and top electrode 140, respectively in adjacent MTJ pillars. As depicted, each portion of ILD 23, ILD 83, ILD 93, ILD 103, and ILD 133 between adjacent MTJ pillars increases in width in semiconductor structure 2100. In other words, ILD 113 above ILD 103 has a larger width than ILD 103 and similarly, ILD 103 is wider than ILD 93 where ILD 103 resides on ILD 93. ILD 93 is wider than ILD 83 and ILD 83 is wider than ILD 23. As depicted in FIG. 21, each of ILD 23, ILD 83, ILD 93, ILD 103, and ILD 133 can be deposited in a low aspect ratio gap (e.g., a thin layer of each layer of ILD is needed to fill the gap to an adjacent MTJ pillar). As depicted in FIG. 21, each of ILD 23, ILD 83, ILD 93, ILD 103, and ILD 133 are void-free. Using more than one layer of ILD between adjacent MTJ pillars can reduce ILD voids and the shorting associated with ILD voids between MTJ pillars and the contacts to the MTJ pillars. As depicted in embodiments of the present invention, five or more layers of ILD deposited between MTJ pillars can provide void-free ILD layers that improve MRAM device yields by reducing shorts created by contact metal deposited into voids in the ILD, which could occur during contact formation if the ILD contains voids.

While the method and materials of the present invention are discussed with respect to MRAM devices, as known to one skilled in the art, the method of forming vertical semiconductor device structures with multiple layers of functional material with a layer of ILD deposited between adjacent portions of the functional material (e.g., channels, phase-change material, etc.) may be applied to other types of semiconductor devices (e.g., vertical field-effect transistors (VFETs), gate-all-around FETs, phase-change memory (PCM), etc.) that may be densely packed.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments of the present invention, the practical application or technical improvement over technologies found in the marketplace, or to enable others of ordinary skill in the art to understand the embodiments disclosed herein.

What is claimed is:

1. A semiconductor structure, the semiconductor structure comprising:
a magnetic tunnel junction (MTJ) pillar for a magnetoresistive random-access memory (MRAM) device, wherein each material layer of the MTJ pillar resides on a lower material layer of the MTJ pillar with a different width.

2. The semiconductor structure of claim 1, wherein the MTJ pillar further comprises:
a bottom electrode on a metal cap;
a reference layer on the bottom electrode, wherein the reference layer is less wide than the bottom electrode;
a tunnel barrier layer on the reference layer, wherein the tunnel barrier layer is wider than the reference layer;
a free layer on the tunnel barrier layer, wherein the free layer is less wide than the tunnel barrier layer; and
a top electrode on the free layer, wherein the top electrode has a tapered shape.

3. The semiconductor structure of claim 2, wherein the reference layer and the free layer have a sidewall encapsulation.

4. The semiconductor structure of claim 3, wherein the reference layer and the free layer have the sidewall encapsulation that is a same dielectric material.

5. The semiconductor structure of claim 3, wherein a width of the reference layer and the sidewall encapsulation around the reference layer is approximately a same width as the tunnel barrier layer.

6. The semiconductor structure of claim 3, wherein a width of the free layer and the sidewall encapsulation around the free layer is approximately a same width as a bottom surface of the top electrode.

7. The semiconductor structure of claim 2, wherein the top electrode has a wider bottom surface than a top surface of the top electrode.

8. The semiconductor structure of claim 2, wherein the top electrode has a top surface that is smaller than a bottom surface forming the top electrode with the tapered shape.

9. The semiconductor structure of claim 2, wherein the top electrode has a cone shape with a flat top surface and a flat bottom surface.

10. The semiconductor structure of claim 3, wherein the reference layer and the free layer have the sidewall encapsulation that is a different dielectric material for the sidewall encapsulation of the free layer than the dielectric material of the sidewall encapsulation of the reference layer.

11. The semiconductor structure of claim 2, further comprising a contact with a contact liner connecting to a top surface of the top electrode.

12. A semiconductor structure of two adjacent magnetoresistive random-access memory devices, the semiconductor structure comprising:
two bottom electrodes separated by a first layer of interlayer dielectric (ILD) material;
two reference layers with a first sidewall encapsulation separated by a second layer of interlayer dielectric material;
two tunnel barrier layers separated by a third layer of ILD material;
two free layers with a second sidewall encapsulation separated by a fourth layer of ILD material;
two top electrodes with a tapered sidewall separated by a fifth layer of ILD material; and
a contact on each of the two top electrodes in the fifth layer of ILD material.

13. The semiconductor structure of claim 12, wherein the first sidewall encapsulant is composed of a different dielectric material than the second sidewall encapsulation.

14. The semiconductor structure of claim 12, wherein the two tunnel barrier layers are each wider than each of the two reference layers.

15. The semiconductor structure of claim 12, wherein the two free layers are each less wide than each of the two tunnel barrier layers.

16. The semiconductor structure of claim 12, wherein a bottom surface of each of the two top electrode is wider than a top surface of each of the two top electrodes.

17. A method of forming a semiconductor structure, the method comprising:
forming two adjacent magnetic tunnel junction pillars of two adjacent magnetoresistive random-access memory devices, wherein each layer of each of the two adjacent magnetic tunnel junction pillars has a different width.

18. The method of claim 17, wherein forming the two magnetic tunnel junction pillars of two adjacent magnetoresistive random-access memory devices, further comprises:
forming two adjacent bottom electrodes in a first layer of interlayer dielectric (ILD) material above a portion of a first metal layer of a middle-of-line metal layer or a back end of line semiconductor layer;
depositing a reference layer on the two adjacent bottom electrodes and the first layer of ILD material;
patterning a hardmask on the reference layer;
removing exposed portions of the reference layer;
removing the hardmask;
forming a sidewall encapsulation around remaining portions of the reference layer;
depositing a second layer of ILD material over the semiconductor structure;
depositing a tunnel barrier layer over the remaining portions of the reference layer, the sidewall encapsulant, and the second layer of ILD material;
forming two adjacent portions of the tunnel barrier layer using a patterned hardmask on the tunnel barrier layer;
depositing and planarizing a third layer of ILD material on the second layer of ILD material and the two adjacent portions of the tunnel barrier layer;
depositing a free layer on the two adjacent portions of the tunnel barrier layer and the third layer of ILD material;
patterning the free layer to form two adjacent portions of the free layer on the two adjacent portions of the tunnel barrier layer;
forming a sidewall encapsulation around the two adjacent portions of the free layer;
depositing a fourth layer of ILD material on the semiconductor structure;
planarizing the fourth layer of ILD material exposing the two adjacent portions of the free layer;
forming two adjacent top electrodes on the two adjacent portions of the free layer using an angled ion beam etch process; and
depositing a fifth layer of ILD material on the fourth layer of ILD material and the two adjacent top electrodes.

19. The method of claim 18, further comprises:
performing a chemical-mechanical polish to expose the two adjacent top electrodes of two adjacent MTJ pillars; and
forming a contact on each of the two adjacent top electrodes, wherein at least the fourth layer of ILD material and the fifth layer of ILD material are void-free preventing shorting of the two adjacent MTJ pillars during contact formation on the two adjacent top electrodes.

20. The method of claim 18, wherein the first layer of ILD material, the second layer of ILD material, the third layer of ILD material, the fourth layer of ILD material, and the fifth layer of ILD material are each selected from the group consisting of: a same dielectric material and different dielectric materials.
